(19) United States
(12) Patent Application Publication
(10) Pub. No.: US 2006/0272574 A1
(43) Pub. Date: Dec. 7, 2006

(54) Methods for manufacturing integrated circuits

(75) Inventors: Andrew Michael Waite, Hopewell Junction, NY (US); Scott Luning, Poughkeepsie, NY (US)

Correspondence Address: INGRASSIA FISHER & LORENZ, P.C., 7150 E. CAMELBACK, STE. 325, SCOTTSDALE, AZ, 85251, US

(73) Assignee: ADVANCED MICRO DEVICES, INC.

(21) Appl. No.: 11/147,600

(22) Filed: Jun. 7, 2005

(51) Int. Cl. C30B 23/00; C30B 25/00; C30B 28/12; C30B 28/14

(52) U.S. Cl. 117/89; 117/92

(57) ABSTRACT

Methods for manufacturing an integrated circuit are provided. An exemplary method comprises the step of providing a silicon substrate having a first crystalline orientation. A silicon layer having a second crystalline orientation is bonded to the silicon substrate. The second crystalline orientation is different from the first crystalline orientation. The silicon layer is etched to expose a portion of the silicon substrate and an amorphous silicon layer is deposited on the exposed portion. The amorphous silicon layer is transformed into a regrown crystalline silicon layer having the first crystalline orientation. A first field effect transistor is formed on the silicon layer and a second field effect transistor is formed on the regrown crystalline silicon layer.

### FIELD OF THE INVENTION

The present invention generally relates to FET ICs and to methods for their manufacture, and more particularly relates to methods for manufacturing FET ICs having PFET and NFET Hybrid Orientation (HOT) devices.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel and N-channel FETs and the IC is then referred to as a complementary MOS or CMOS circuit. Certain improvements in performance of FET ICs can be realized by forming the FETs in silicon substrates having particular crystalline orientation. The silicon substrate in which the FETs typically are fabricated is usually of <100> crystalline orientation. This crystalline orientation is selected because the <100> crystalline orientation results in the highest electron mobility and thus the highest speed N-channel FETs. Additional performance enhancements can be realized in a CMOS circuit by enhancing the mobility of holes in the P-channel FETs. The mobility of holes can be enhanced by fabricating the P-channel FETs on silicon having a <110> crystalline orientation. Hybrid orientation techniques (HOT) use <100> crystalline orientation for N-channel FETs and <110> crystalline orientation for P-channel FETs.

Accordingly, it is desirable to provide a method for manufacturing CMOS integrated circuits that combine HOT N-channel and P-channel FETS on the same bulk substrate. In addition, it is desirable to provide a method for fabricating a silicon substrate that provides for varying carrier mobility. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

In accordance with an exemplary embodiment of the present invention, a method is provided for manufacturing an integrated circuit. The method comprises the step of providing a silicon substrate having a first crystalline orientation. A silicon layer having a second crystalline orientation is bonded to the silicon substrate. The second crystalline orientation is different from the first crystalline orientation. The silicon layer is etched to expose a portion of the silicon substrate and an amorphous silicon layer is deposited on the exposed portion. The amorphous silicon layer is transformed into a regrown crystalline silicon layer having the first crystalline orientation. A first field effect transistor is formed on the silicon layer and a second field effect transistor is formed on the regrown crystalline silicon layer.

In accordance with another exemplary embodiment of the present invention, a method for fabricating a silicon substrate providing varying carrier mobility is provided. The method comprises the step of providing a first silicon layer having a first crystalline orientation, a first region, and a second region. A second silicon layer having a second crystalline orientation is disposed on the first region of the first silicon layer. The second crystalline orientation is different from the first crystalline orientation. An amorphous silicon layer is disposed on the second region of the first silicon layer. The amorphous silicon layer is transformed into a regrown crystalline silicon layer having the first crystalline orientation.

In accordance with a further exemplary embodiment of the present invention, a method for fabricating a CMOS structure is provided. The method comprises the step of providing a silicon substrate having a first crystalline orientation and disposing a silicon layer having a second crystalline orientation on the silicon substrate. The second crystalline orientation is different from the first crystalline orientation. The silicon layer is etched to form a trench that exposes a portion of the silicon substrate and a spacer is formed on a sidewall of the trench. An amorphous silicon layer is deposited within the trench and is regrown to form a regrown crystalline silicon layer having the first crystalline orientation. Either an N-channel field effect transistor or a P-channel field effect transistor is formed on the silicon layer and the other of an N-channel field effect transistor or a P-channel field effect transistor is formed on the regrown crystalline silicon layer.

### BRIEF DESCRIPTION OF THE DRAWINGS

The present invention will hereinafter be described in conjunction with the following drawing figures, wherein like numerals denote like elements, and wherein:

FIGS. 1-18 illustrate schematically, in cross section, an embodiment of an integrated circuit and method steps for its manufacture.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

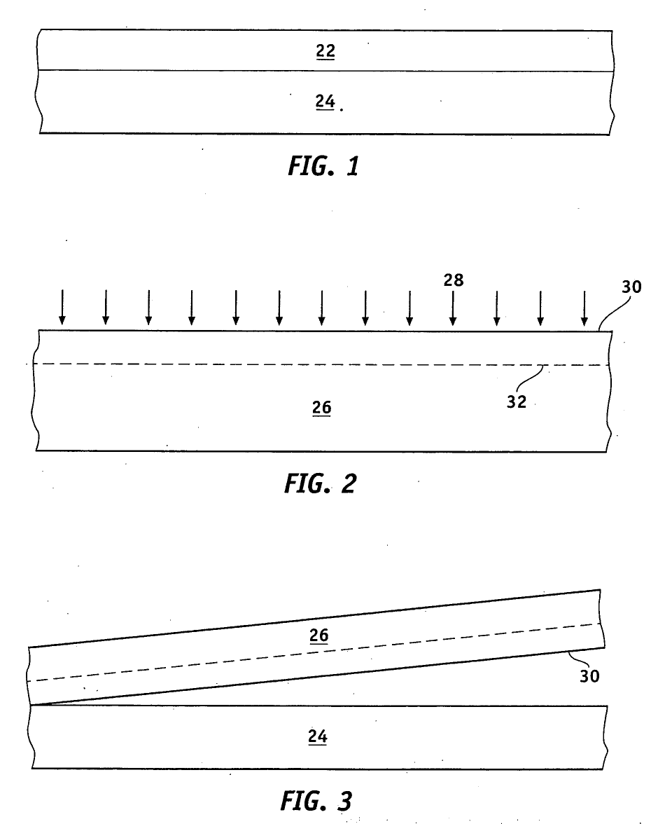

FIGS. 1-18 schematically illustrate a CMOS integrated circuit 20 and method steps for the manufacture of such a CMOS integrated circuit in accordance with various embodiments of the present invention. In these illustrative embodiments, the fabrication of only one P-channel FET and one N-channel FET of CMOS integrated circuit 20 is illustrated. However, it will be understood that any suitable number of P-channel FETs and N-channel FETs of CMOS integrated circuit 20 may be fabricated. Various steps in the manufacture of CMOS devices are well known and so, in the interest of brevity, many conventional steps will only be mentioned briefly herein or will be omitted entirely without providing the well known process details.

As illustrated in FIG. 1, the method in accordance with one embodiment of the invention begins with a silicon layer 22 disposed on a silicon carrier substrate 24. As used herein, the terms “silicon layer” and “silicon substrate” will be used to encompass the relatively pure silicon materials typically used in the semiconductor industry as well as silicon admixed with other elements such as germanium, carbon, and the like to form crystalline semiconductor material. Silicon layer 22 and silicon carrier substrate 24 will be used in the formation of bulk hybrid orientation (HOT) transistors. Accordingly, the silicon layer and the silicon carrier substrate have different crystalline orientations. One of the silicon layer or the silicon carrier substrate may be selected to have a <100> crystalline orientation and the other may be selected to have a <110> crystalline orientation. In a preferred embodiment, but without limitation, the silicon layer will have a <100> crystalline orientation and the silicon carrier substrate will have a <110> crystalline orientation. In an alternate embodiment of the invention, the silicon layer will have a <110> crystalline orientation and the silicon carrier substrate will have a <100> crystalline orientation. By <100> crystalline orientation or <110> crystalline orientation is meant a macroscopic surface that is within about ±2° of the true crystalline orientation. Both the silicon layer and the silicon carrier substrate preferably have a resistivity of at least about 18-33 Ohms per square. The silicon can be impurity doped either N-type or P-type, but is preferably doped P-type.

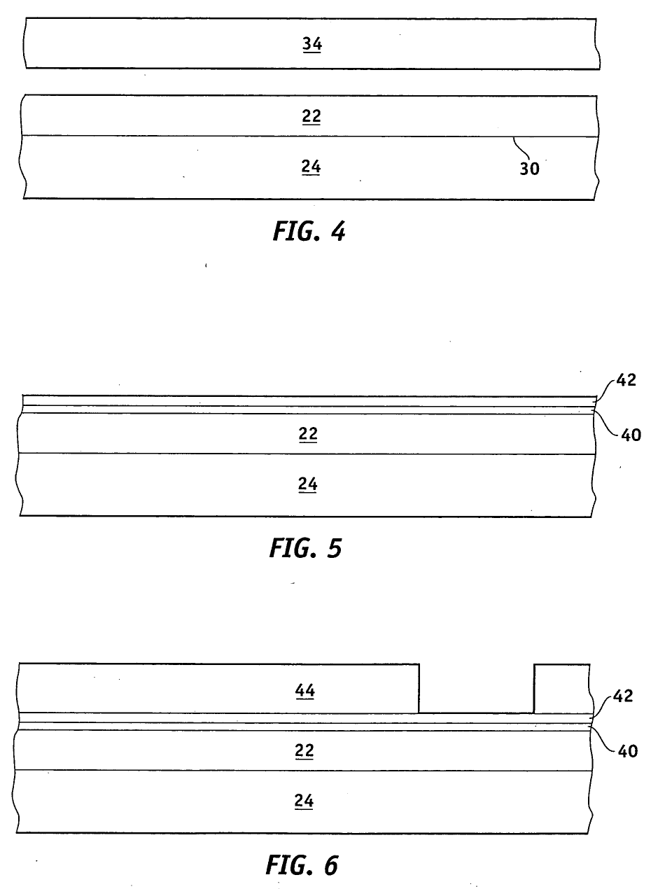

Silicon layer 22 is disposed on silicon carrier substrate 24 by any suitable well-known technique, such as a wafer bonding technique. For example, silicon layer 22 may be bonded to silicon carrier substrate 24 by a conventional layer transfer technique illustrated in FIGS. 2-4. Referring to FIG. 2, hydrogen, illustrated with arrows 28, is implanted into a surface 30 of a silicon substrate 26 to create damage, illustrated by dashed line 32, that later enables a top silicon layer to fracture from the substrate. Surface 30 of silicon substrate 26 then is flip-bonded to silicon carrier substrate 24, as illustrated in FIG. 3. Silicon substrate 26 then is subjected to heat treatment, as is well-known in the art. As illustrated in FIG. 4, the heat treatment splits the hydrogen-implanted silicon substrate 26 along dashed line 32 into silicon layer 22 and a disposable remainder portion 34 and strengthens the bonding between silicon layer 22 and silicon carrier substrate 24. The top surface of silicon layer 22 then can be thinned and polished, for example, by chemical mechanical planarization (CMP), to a thickness of about 300 to about 500 nanometers (nm) to form an atomically smooth surface.

As illustrated in FIG. 5, after the silicon layer 22 is disposed onto the silicon carrier substrate 24, the silicon layer 22 is oxidized to form a thin pad oxide 40 having a thickness of about 5-20 nm, preferably about 10-12 nm, on the exposed surface of silicon layer 22. A layer 42 of silicon nitride having a thickness of about 50-200 nm, preferably about 100 nm, then is deposited on top of pad oxide 40. The silicon nitride can be deposited, for example, by low pressure chemical vapor deposition (LPCVD) or plasma enhanced chemical vapor deposition (PECVD) from the reaction of dichlorosilane and ammonia. The silicon nitride layer will subsequently be used as a CMP polish stop, as explained below.

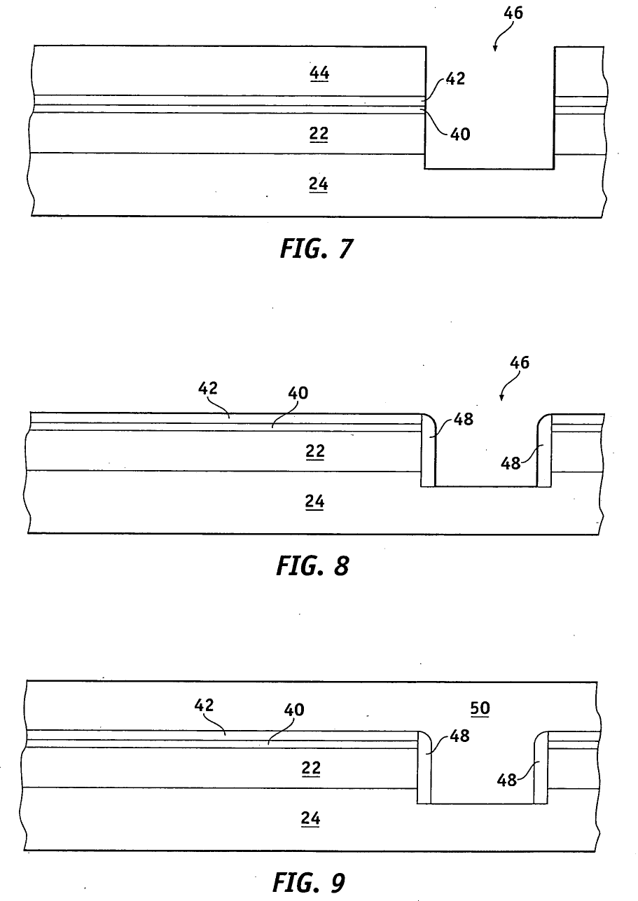

A layer 44 of photoresist is applied to the surface of silicon nitride layer 42 and is photolithographically patterned as illustrated in FIG. 6. Referring to FIG. 7, the patterned photoresist layer is used as an etch mask and a trench 46 is etched through the layers of silicon nitride 42, pad oxide 40, silicon layer 22, and into an upper portion of silicon carrier substrate 24. The trench can be etched by a reactive ion etch (RIE) process using a CF₄ or CHF₃ chemistry to etch the oxide and nitride layers and a chlorine or hydrogen bromide chemistry to etch the silicon. Layer 44 of photoresist is removed after completing the etching of trench 46. Alternatively, photolithographically patterned layer 44 of photoresist can be removed after being used as an etch mask for the etching of silicon nitride layer 42. The etched layer of silicon nitride then can be used as a hard mask to mask the etching of oxide 36 and silicon layer 22. Also in this alternate process, the etch step is terminated after etching into the top portion of silicon carrier substrate 24.

After removing photoresist layer 44, a layer of silicon oxide or silicon nitride is deposited over the surface of the structure including into trench 46. The layer of oxide or nitride is anisotropically etched, for example by RIE, to form sidewall spacers 48 on the vertical sidewalls of trench 46, as illustrated in FIG. 8.

Referring now to FIG. 9, an amorphous silicon layer 50 is deposited on the exposed surface of silicon carrier substrate 24 at the bottom of trench 46. The amorphous silicon layer 50 may be deposited by any suitable technique such as, for example, furnace deposition. The amorphous silicon layer can be deposited by the reduction of silane (SiH₄) at a temperature that is sufficiently low to permit the deposition of amorphous silicon and minimize or, preferably prevent, the deposition of polycrystalline silicon. Preferably, the amorphous silicon is deposited at a temperature within the range of about 500 to about 600° C. The amorphous silicon layer can be deposited to any suitable thickness sufficient to fill trench 46.

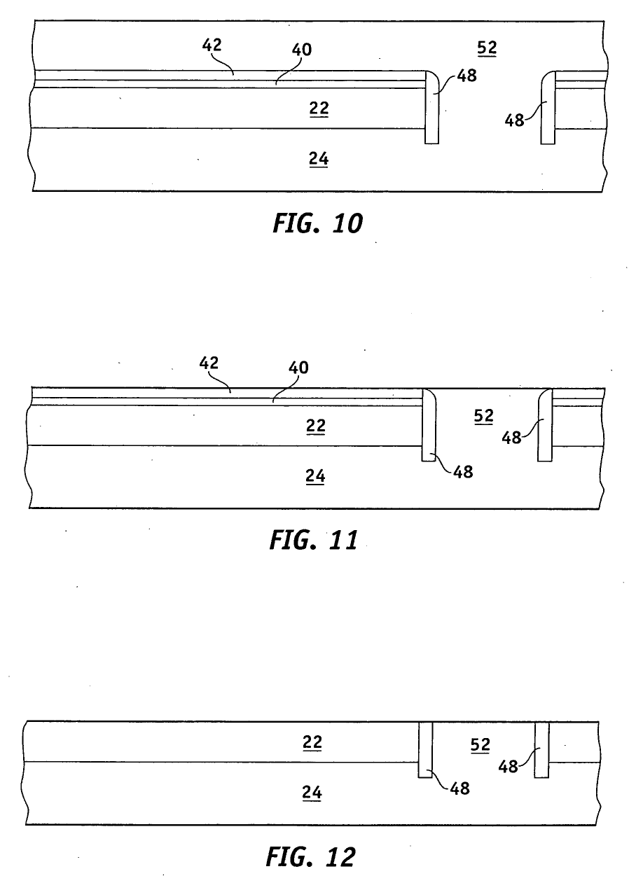

The amorphous silicon layer 50 then is subjected to solid phase epitaxial regrowth that transforms the amorphous silicon layer 50 into layer 52 of regrown crystalline silicon, as illustrated in FIG. 10. The regrown crystalline silicon layer 52 regrows with a crystalline orientation that aligns to the crystalline orientation of the silicon material upon which it is grown. In the preferred embodiment, the regrown crystalline silicon is regrown with the same <110> crystalline orientation as silicon carrier substrate 24. Sidewall spacers 48 minimize or prevent the nucleation of crystalline silicon on the sidewalls of trench 46. In the absence of the sidewall spacers, regrown crystalline silicon may nucleate on the exposed silicon at the edges of the trench 46 as well as on the bottom of the trench resulting in less than ideal crystalline silicon layer. In one embodiment of the invention, the amorphous silicon is regrown and transformed into crystalline silicon by subjecting the amorphous silicon layer 50 to a temperature in the range of about 650 to about 800° C. for about one-half to one hour. In another embodiment of the invention, after regrowth of the amorphous silicon layer 50, the regrown crystalline silicon layer 52 is heated to a temperature in the range of about 1000 to about 1100° C. to facilitate the removal of grain boundaries.

Some overdeposition of the amorphous silicon 50 may occur on the top surface of silicon nitride layer 42 and, accordingly, grain boundaries may form in the overdeposited silicon during the epitaxial regrowth. As will be appreciated, a plurality of trenches 46 may be simultaneously formed in silicon layer 22 for the fabrication of a plurality of FET devices of IC 20. Epitaxial regrowth of the silicon in the trenches commences at the exposed surface of silicon carrier substrate 24 and advances through the trenches and through the overdeposited amorphous silicon. As the regrowth of the amorphous silicon layer continues from within each trench 46 to the overdeposited amorphous silicon, the various crystalline structures within the various trenches may meet on the top surface of silicon nitride layer 42, forming grain boundaries. To remove the overdeposited silicon, and hence any grain boundaries formed in the overdeposited silicon, CMP may be performed, as illustrated in FIG. 11. In this regard, silicon nitride layer 42 is used as a polish stop for the CMP.

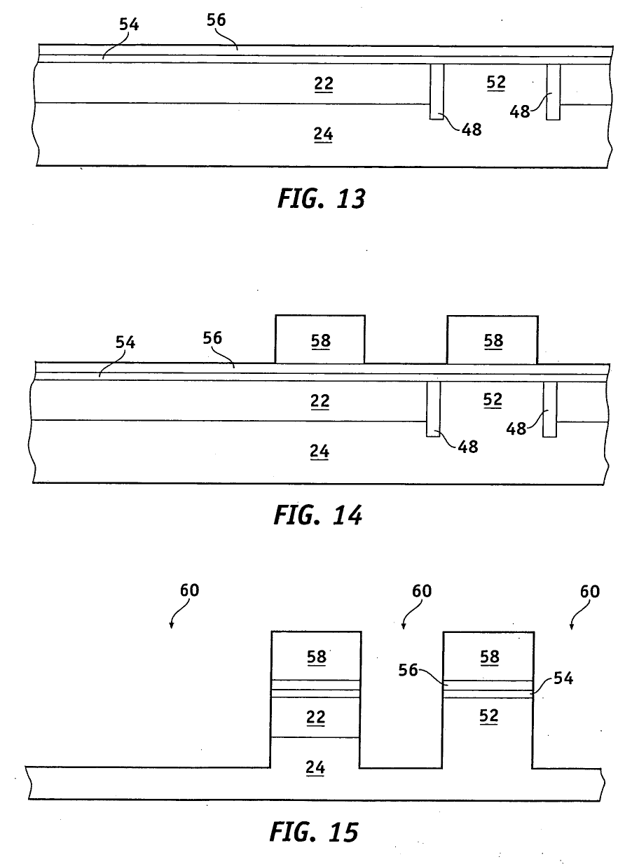

Referring to FIG. 12, silicon nitride layer 42 and pad oxide layer 40 are stripped from the surface of silicon layer 22 using any process well-known in the art and CMP is performed so that the top surfaces of silicon layer 22 and regrown crystalline silicon layer 52 are substantially coplanar. (Alternatively, an oxidation may be performed before nitride strip so that the top silicon surfaces of 22 and 52 are coplanar after nitride and oxide stripping.) As illustrated in FIG. 13, silicon layer 22 and regrown crystalline silicon layer 52 are oxidized to form a thin pad oxide 54 having a thickness of about 5-20 nm, preferably about 10-12 nm, on the surface of silicon layer 22 and regrown crystalline silicon layer 52. A layer 56 of silicon nitride having a thickness of about 50-200 nm, preferably about 100 nm, then is deposited on top of pad oxide 54. The pad oxide layer 54 and silicon nitride layer 56 can be grown as described above for pad oxide layer 40 and silicon nitride layer 42 illustrated in FIG. 5.

A layer 58 of photoresist is applied to silicon nitride layer 56 and is patterned, as illustrated in FIG. 14. Spacers 48 are removed and trenches 60 are formed by reactive ion etching using the patterned layer of photoresist as an etch mask, as illustrated in FIG. 15.

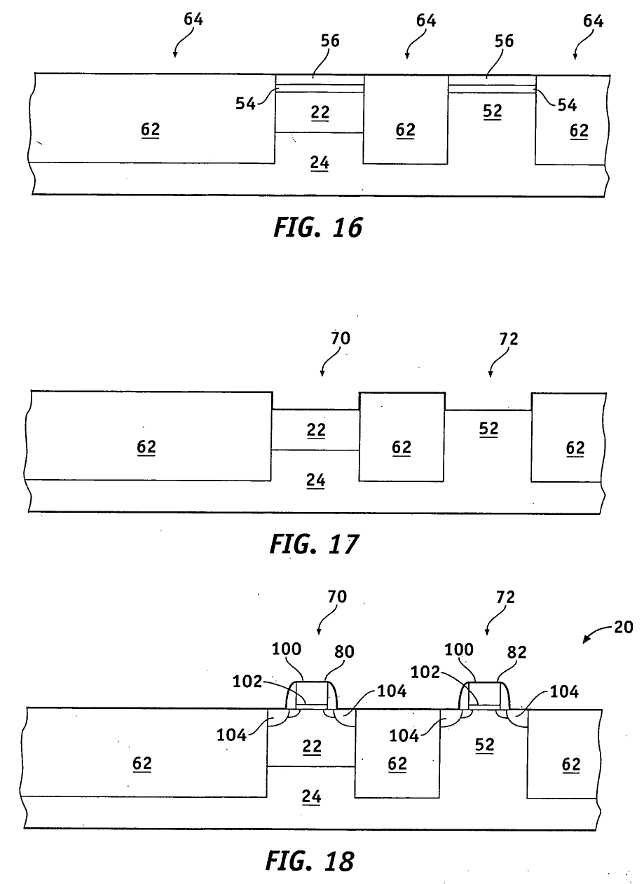

Referring to FIG. 16, after removing spacers 48 and forming trenches 60, layer 58 of photoresist is removed and trenches 60 are filled with a deposited oxide or other insulator 62, for example, by LPCVD or PECVD. Deposited insulator 62 fills trenches 60, but is also deposited onto silicon nitride layer 56. The excess insulator on silicon nitride layer 56 is removed using CMP to complete the formation of shallow trench isolation (STI) 64. Silicon nitride layer 56 is used as a polish stop during the CMP process. Those of skill in the art will recognize that many known processes and many known materials can be used to form STI or other forms of electrical isolation between devices making up the integrated circuit, and, accordingly, those known processes and materials need not be discussed herein.

After removal of the excess insulator by CMP, the remaining silicon nitride layer 56 and pad oxide 54 are stripped, exposing silicon layer 22 and regrown crystalline silicon layer 52, as illustrated in FIG. 17. The structure illustrated in FIG. 17 includes two silicon regions 70 and 72, one of which has a <100> crystalline orientation and the other of which has a <110> crystalline orientation. Following the formation of the shallow trench isolation, silicon layer 22 and regrown crystalline silicon layer 52 in regions 70 and 72, respectively, can be appropriately impurity doped in a known manner, for example, by ion implantation. In accordance with the preferred embodiment of the invention, silicon region 72 has <110> crystalline orientation and is impurity doped with N-type impurities and silicon region 70 has <100> crystalline orientation and is impurity doped with P-type impurities. Regardless of whether regrown crystalline silicon layer 52 is <110> crystalline orientation and silicon layer 22 is <100> crystalline orientation, or whether regrown crystalline silicon layer 52 is <100> crystalline orientation and silicon layer 22 is <110> crystalline orientation, the <100> crystalline orientation region is impurity doped with P-type impurities and the <110> crystalline orientation region is impurity doped with N-type impurities. Impurity doping of the various regions can be carried out in well known manner, with implant species, doses, and energies determined by the type of devices to be fabricated. Implantation of selected regions can be carried out by masking other areas, for example, with patterned photoresist.

Referring to FIG. 18, after stripping the remainder of silicon nitride layer 56 and pad oxide 54, the substantially coplanar surfaces of silicon region 70 and silicon region 72 are exposed and the structure is ready for the fabrication of FETs necessary for implementing the desired integrated circuit function. The fabrication of the HOT N-channel and P-channel FETs in regions 70 and 72, respectively, can be carried out using conventional CMOS processing techniques. Various processing flows for fabricating CMOS devices are well known to those of skill in the art and need not be described herein. Those of skill in the art know that the various processing flows depend on parameters such as the minimum geometries being employed, the power supplies available for powering the IC, the processing speeds expected of the IC, and the like. Regardless of the processing flow employed for completing the fabrication of the IC, IC 20 in accordance with one embodiment of the invention includes a bulk N-channel HOT FET 80 fabricated in silicon region 70 having <100> crystalline orientation, and a bulk P-channel HOT FET 82 fabricated in silicon region 72 having <110> crystalline orientation. In the illustrated embodiment, silicon carrier substrate 24 and regrown crystalline silicon layer 52 are of <110> crystalline orientation and P-channel HOT FET 82 is formed in region 72. Also in accordance with the illustrated embodiment, silicon layer 22 is of <100> orientation and N-channel HOT FET 80 is formed in region 70. The selection of <110> crystalline orientation for silicon carrier substrate 24 in this illustrative embodiment is arbitrary; those of skill in the art will appreciate that the crystalline orientation of silicon carrier substrate 24 and silicon layer 22 can be interchanged without departing from the scope and intent of the invention.

As illustrated in FIG. 18, each of bulk HOT FETs 80 and 82 include a gate electrode 100 overlying a gate insulator 102 with source and drain regions 104 positioned on each side of the gate electrode. The gate electrodes can be polycrystalline silicon, metal, silicide, or the like. The gate insulators can be silicon dioxide, silicon oxynitride, a high dielectric constant material, or the like, as required for the particular circuit function being implemented. The source and drain regions can consist of a single impurity doped region or a plurality of aligned impurity doped regions. Although not illustrated, conductive contacts and conductive traces can be coupled to appropriate gate electrodes and source and drain regions to interconnect the various transistors of the integrated circuit.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for manufacturing an integrated circuit comprising the steps of:
providing a silicon substrate having a first crystalline orientation;
bonding a silicon layer having a second crystalline orientation to said silicon substrate, said second crystalline orientation being different than said first crystalline orientation;
etching through said silicon layer to expose a portion of said silicon substrate;
depositing an amorphous silicon layer on said exposed portion of said silicon substrate;
transforming said amorphous silicon layer to a regrown crystalline silicon layer having said first crystalline orientation; and
forming a first field effect transistor on said silicon layer and a second field effect transistor on said regrown crystalline silicon layer.

2. The method of claim 1, wherein the step of providing a silicon substrate having a first crystalline orientation comprises the step of providing a silicon substrate having a <110> crystalline orientation and the step of bonding a silicon layer having a second crystalline orientation comprises the step of bonding a silicon layer having a <100> crystalline orientation.

3. The method of claim 2, wherein the step of forming a first field effect transistor comprises the step of forming an N-channel field effect transistor and the step of forming a second field effect transistor comprises the step of forming a P-channel field effect transistor.

4. The method of claim 1, wherein the step of transforming comprises the step of regrowing by solid phase epitaxial regrowth.

5. The method of claim 4, wherein the step of transforming comprises the step of subjecting said amorphous silicon layer to a temperature in the range of about 650 to about 800° C. for about one-half to one hour.

6. The method of claim 1, further comprising the step of heating said regrown crystalline silicon layer to a temperature in the range of about 1000 to 1100° C., wherein the step of heating is performed after the step of transforming and before the step of forming.

7. A method for fabricating a silicon substrate providing varying carrier mobility, the method comprising the steps of:
providing a first silicon layer having a first crystalline orientation, a first region, and a second region;
disposing a second silicon layer having a second crystalline orientation on said first region of said first silicon layer, the second crystalline orientation being different than the first crystalline orientation;
disposing an amorphous silicon layer on said second region of said first silicon layer; and
transforming said amorphous silicon layer to a regrown crystalline silicon layer having said first crystalline orientation.

8. The method of claim 7, wherein the step of providing a first silicon layer having a first crystalline orientation comprises the step of providing a first silicon layer having a <110> crystalline orientation and the step of disposing a second silicon layer having a second crystalline orientation comprises the step of disposing a second silicon layer having a <100> crystalline orientation.

9. The method of claim 7, wherein the step of providing a first silicon layer having a first crystalline orientation comprises the step of providing a first silicon layer having a <100> crystalline orientation and the step of disposing a second silicon layer having a second crystalline orientation comprises the step of disposing a second silicon layer having a <110> crystalline orientation.

10. The method of claim 7, wherein the step of transforming comprises the step of regrowing by solid phase epitaxial regrowth.

11. The method of claim 10, wherein the step of transforming comprises the step of subjecting said amorphous silicon layer to a temperature in the range of about 650 to about 800° C. for about one-half to one hour.

12. A method for fabricating a CMOS structure, the method comprising the steps of:
providing a silicon substrate having a first crystalline orientation;
disposing a silicon layer having a second crystalline orientation onto said silicon substrate, said second crystalline orientation being different than said first crystalline orientation;
etching through said silicon layer to form a first trench that exposes a portion of said silicon substrate;
forming a spacer on a sidewall of said first trench;
depositing an amorphous silicon layer within said first trench;
heating said amorphous silicon layer to form a regrown crystalline silicon layer having said first crystalline orientation; and
forming one of an N-channel field effect transistor or a P-channel field effect transistor on said silicon layer and the other of said N-channel field effect transistor or a P-channel field effect transistor on said regrown crystalline silicon layer.

13. The method of claim 12, wherein the step of providing a silicon substrate having a first crystalline orientation comprises the step of providing a silicon substrate having a <110> crystalline orientation and the step of, disposing a silicon layer having a second crystalline orientation onto said silicon substrate comprises the step of disposing a silicon layer having a <100> crystalline orientation onto said silicon substrate.

14. The method of claim 13, further comprising the step of impurity doping said silicon layer with P-type impurities and the step of impurity doping said regrown crystalline silicon layer with N-type impurities.

15. The method of claim 13, wherein the step of forming an N-channel field effect transistor or a P-channel field effect transistor on said silicon layer comprises the step of forming an N-channel field effect transistor on said silicon layer and the step of forming the other of an N-channel field effect transistor or a P-channel field effect transistor on said regrown crystalline silicon layer comprises forming a P-channel field effect transistor on said regrown crystalline silicon layer.

16. The method of claim 12, wherein the step of providing a silicon substrate having a first crystalline orientation comprises the step of providing a silicon substrate having a <100> crystalline orientation and the step of disposing a silicon layer having a second crystalline orientation onto said silicon substrate comprises the step of disposing a silicon layer having a <110> crystalline orientation onto said silicon substrate.

17. The method of claim 16, further comprising the step of impurity doping said silicon layer with N-type impurities and the step of impurity doping said regrown crystalline silicon layer with P-type impurities.

18. The method of claim 17, wherein the step of forming an N-channel field effect transistor or a P-channel field effect transistor on said silicon layer comprises the step of forming a P-channel field effect transistor on said silicon layer and the step of forming the other of an N-channel field effect transistor or a P-channel field effect transistor on said regrown crystalline silicon layer comprises forming a N-channel field effect transistor on said regrown crystalline silicon layer.

19. The method of claim 12, further comprising the step of anisotropically etching to remove said sidewall spacer and to form a second trench.

20. The method of claim 19, further comprising the step of filling said second trench with a dielectric material.
